(19) United States
(12) Patent Application Publication
(10) Pub. No.: US 2017/0374762 A1
(43) Pub. Date: Dec. 28, 2017

(54) HEAT PIPE ASSEMBLY AND ELECTRONIC DEVICE

(71) Applicant: Foxconn Technology Co., Ltd., New Taipei (TW)

(72) Inventors: NIEN-TIEN CHENG, New Taipei (TW); JUI-WEN HUNG, New Taipei (TW)

(21) Appl. No.: 15/485,380

(22) Filed: Apr. 12, 2017

(30) Foreign Application Priority Data
Jun. 27, 2016 (CN) 201620645839.5

(51) Int. Cl. H05K 7/20; F28F 1/00

(52) U.S. Cl. CPC H05K 7/20336; F28F 1/006; F28F 2280/02; F28F 2275/143

(57) ABSTRACT

A heat pipe assembly comprises a female heat pipe comprising at least one open end; and at least one male heat pipe. The at least one male heat pipe includes an inserting end where the inserting end of the at least one male heat pipe is able to be movably inserted into an open end of the female heat pipe. An electronic device using the heat pipe assembly is also provided.

### FIELD

The subject matter herein generally relates to a heat pipe assembly and an electronic device using the heat pipe assembly.

### BACKGROUND

Electronic components such as central processing units (CPUs) generate heat during operation. Thus, heat dissipation devices, such as heat pipes, are used to dissipate the heat generated. While heat pipes are useful, a heat pipe with a better structure is needed.

### BRIEF DESCRIPTION OF THE DRAWINGS

Implementations of the present technology will now be described, by way of example only, with reference to the attached figures.

FIG. 1 is a diagrammatic view of a heat pipe assembly according to a first exemplary embodiment of the present application.

FIG. 2 is an exploded perspective view of the heat pipe assembly of FIG. 1.

FIG. 3 is a cross-sectional view taken along line of FIG. 1.

FIG. 4 is a diagrammatic view of a heat pipe assembly according to a second exemplary embodiment of the present application.

FIG. 5 is a diagrammatic view of an electronic device using the heat pipe assembly of FIG. 4.

FIG. 6 is a cross-sectional view taken along line VI-VI of FIG. 5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to illustrate details and features of the present disclosure better.

Several definitions that apply throughout this disclosure will now be presented.

The term “comprising” when utilized, means “including, but not necessarily limited to”; it specifically indicates open-ended inclusion or membership in the so-described combination, group, series, and the like. The term “about” when utilized, means “not only include the numerical value, but also include numbers closest to the numerical value”.

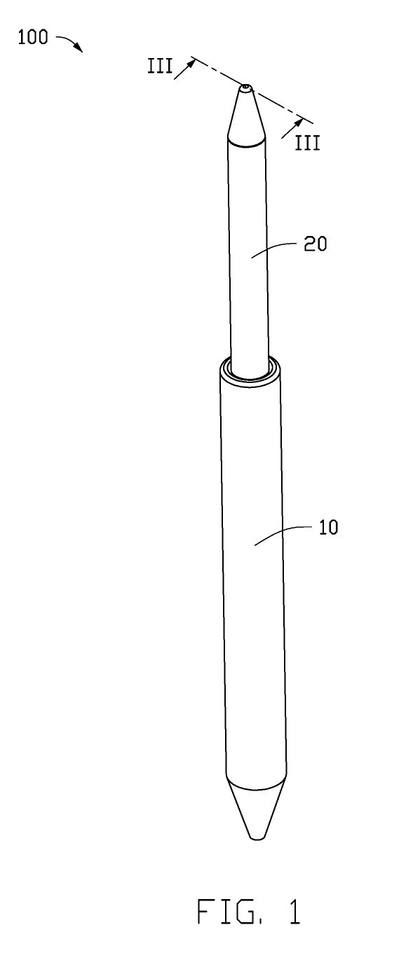

FIG. 1 illustrates a first exemplary embodiment of a heat pipe assembly 100 including a female heat pipe 10 and a male heat pipe 20. An end of the male heat pipe 20 can be movably inserted into an end of the female heat pipe 10.

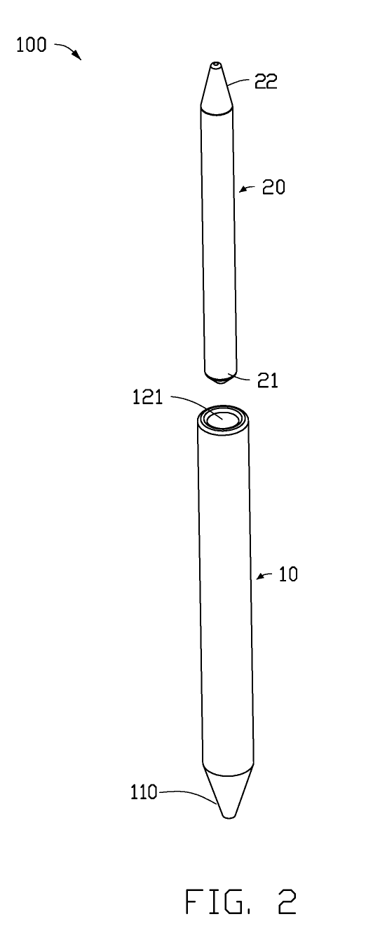

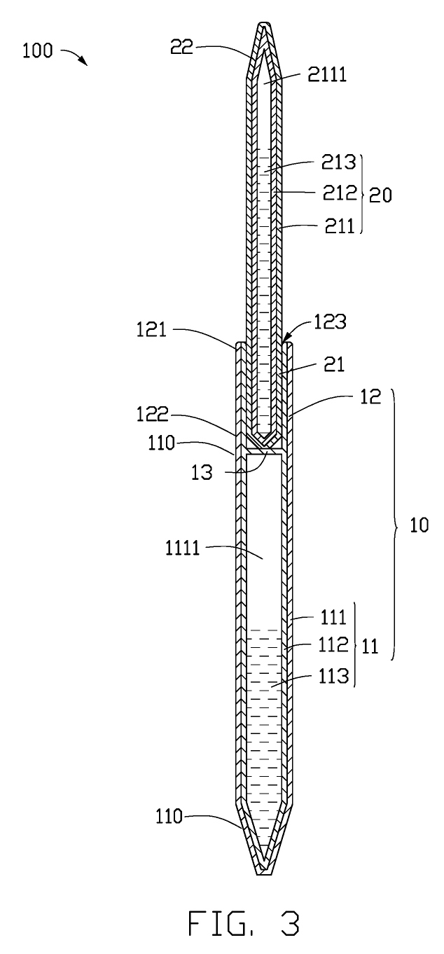

Referring to FIG. 2 and FIG. 3, the female heat pipe 10 includes a straight dissipation section 11, a sleeve 12 integrally formed with the dissipation section 11, and an end surface 13 positioned between the dissipation section 11 and the sleeve 12. The dissipation section 11 and the sleeve 12 are separated by the end surface 13. The dissipation section 11 comprises a closed end 110 facing away from the end surface 13. The end surface 13 may be flat or curved.

The sleeve 12 includes an open end 121 facing away from the end wall 13. The open end 121 defines an opening 123.

The dissipation section 11 includes a first casing 111, a first wick structure 112 attached to an inner surface of the first casing 111, and a working medium 113 filled in the first casing 111. The sleeve 12 extends straight from the first casing 111.

The first casing 111 defines a first sealed cavity 1111. The working medium 113 is filled in the first sealed cavity 1111.

The first casing 111 may comprise only one metal layer or at least two metal layer stacked together. The metal layer is made of metal such as copper, silver, aluminum, stainless steel, or carbon steel.

The first wick structure 112 may be made of metal mesh, carbon nanotube array, or any combination thereof.

The first working medium 113 may be selected from, for example, water, alcohol, ammonia, or any combination thereof.

The first sealed cavity 1111 can maintain a vacuum state.

The male heat pipe 20 includes an inserting end 21 and a free end 22 opposite to the inserting end 21. The inserting end 21 can be inserted into the sleeve 12 of the female heat pipe 10 through the opening 123. The inserting end 21 and the free end 22 are closed ends. An external diameter of the inserting end 21 is smaller than or equal to the internal diameter of the opening 123, so that the inserting end 21 can be inserted into the sleeve 12.

The male heat pipe 20 includes a second casing 211, a second wick structure 212 attached to an inner surface of the second casing 211, and a second working medium 213 filled in the second casing 211.

The second casing 211 defines a second sealed cavity 2111. The second working medium 213 is filled in the second sealed cavity 2111.

The second casing 211 may comprise only one metal layer or at least two metal layer stacked together. The metal layer is made of metal such as copper, silver, aluminum, stainless steel, or carbon steel.

The second wick structure 212 may be made of metal mesh, carbon nanotube array, or any combination thereof.

The second working medium 213 may be selected from water, alcohol, ammonia, or any combination thereof.

The second sealed cavity 2111 can maintain a vacuum state.

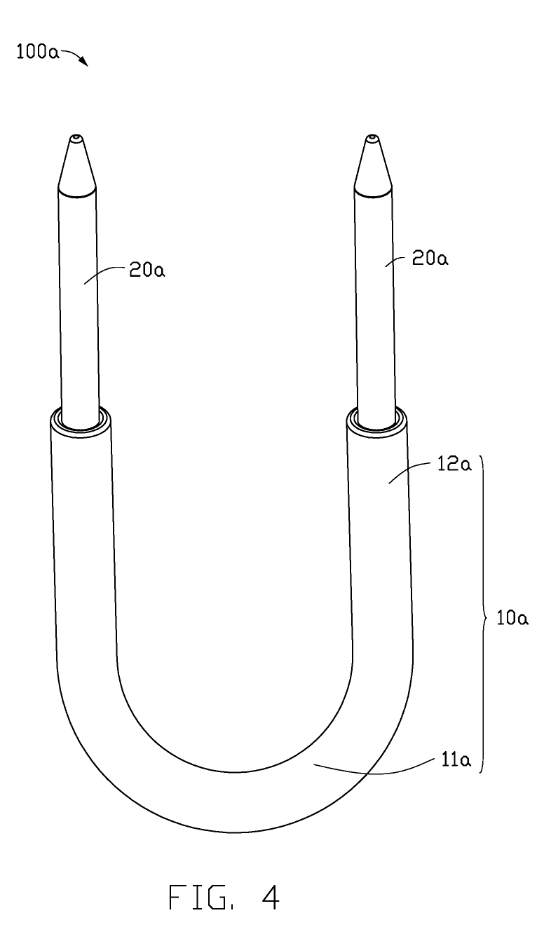

FIG. 4 illustrates a second exemplary embodiment of a heat pipe assembly 100a including a female heat pipe 10a and at least two male heat pipes 20a. An end of each of the male heat pipes 20a can be inserted into an end of the female heat pipe 10a.

The female heat pipe 10a includes a U-shaped dissipation section 11a and at least two sleeves 12a integrally formed with the dissipation section 11a. The number of the sleeves 12a is equal to the number of the male heat pipes 20a.

The male heat pipes 20a and the sleeves 12a have the same structures as the male heat pipe 20 and the sleeve 12, respectively, of the heat pipe assembly 100 in the first exemplary embodiment. Different from the dissipation section 11 of the heat pipe assembly 100 of the first exemplary embodiment, the dissipation section 11a is U-shaped and comprises two ends, and the male heat pipes 20a extend straight from the two end portions of the dissipation section 11a.

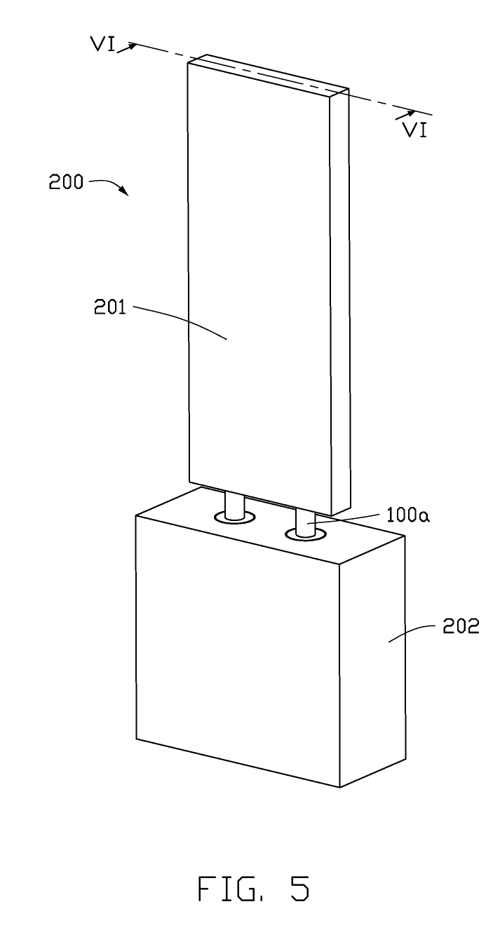

FIG. 5 illustrates an electronic device 200 including a main device 201, an auxiliary device 202, and at least one heat pipe assembly. The at least one heat pipe assembly connects the main device 201 to the auxiliary device 202. The main device 201 may be a master computer with slave or auxiliary devices connected. The auxiliary device 202 may be a display or a loudspeaker. The at least one heat pipe assembly may be the heat pipe assembly 100, the heat pipe assembly 100a, or any combination thereof.

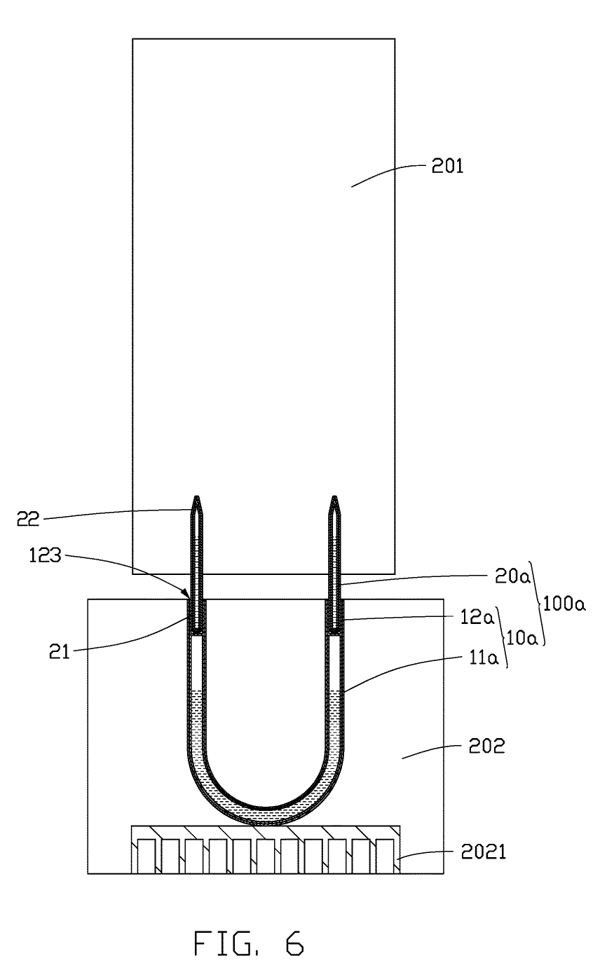

Referring to FIG. 6, in at least one exemplary embodiment, the electronic device 200 comprises a heat pipe assembly 100a, such as the heat pipe assembly 100a in FIG. 4. Two male heat pipes 20a are mounted in the main device 201. A female heat pipe 10a is mounted in the auxiliary device 202. The free end 22 of each male heat pipe 20a is mounted in the main device 201. The inserting ends 21 protrude out of the main device 201. In at least one exemplary embodiment, the free ends 22 is in thermal contact with a heat-generating component such as a central processing unit (CPU). The female heat pipe 10a is mounted in the auxiliary device 202. The openings 123 of female heat pipe 10a are exposed from the auxiliary device 202. The inserting end 21 of each of the male heat pipes 20a is inserted into a respective one of the openings 123. Thereby, when the main device 201 generates heat, a large portion of the heat can be transmitted to the auxiliary device 202 through the heat pipe assembly 100a, to be dissipated by the auxiliary device 202. When the auxiliary device 202 generates heat, a large portion of the heat can be transmitted to the main device 201 through the heat pipe assembly 100a, to be dissipated by the main device 201.

In at least one exemplary embodiment, the auxiliary device 202 includes a heat dissipation component 2021. The dissipation section 11a of the female heat pipe 10a is in thermal contact with the heat dissipation component 2021. The heat dissipation component 2021 can dissipate the heat transmitted from the main device 201.

In another exemplary embodiment, the two male heat pipes 20a may be mounted in the auxiliary device 202. The female heat pipe 10a may be mounted in the main device 201.

The embodiments shown and described above are only examples. Even though numerous characteristics and advantages of the present technology have been set forth in the foregoing description, together with details of the structures and function of the present disclosure, the disclosure is illustrative only, and changes can be made in the detail, including in matters of shape, size, and arrangement of the parts within the principles of the present disclosure, up to and including, the full extent established by the broad general meaning of the terms used in the claims.

What is claimed is:

1. A heat pipe assembly comprising:
a female heat pipe comprising at least one open end; and
at least one male heat pipe comprising an inserting end;
wherein the inserting end of the at least one male heat pipe is able to be movably inserted into the at least one open end.

2. The heat pipe assembly of claim 1, wherein the female heat pipe comprises a dissipation section and at least one sleeve integrally formed with the dissipation section, the at least one open end is situated in the at least one sleeve.

3. The heat pipe assembly of claim 2, wherein the dissipation section is straight.

4. The heat pipe assembly of claim 2, wherein the dissipation section is U-shaped and comprises two ends, two sleeves are integrally formed with and extend from the two ends.

5. The heat pipe assembly of claim 1, wherein the at least one male heat pipe further comprises a free end opposite to the inserting end.

6. The heat pipe assembly of claim 5, wherein the inserting end and the free end are closed ends.

7. An electronic device comprising:
a main device;
an auxiliary device; and
at least one heat pipe assembly comprising:
a female heat pipe mounted in the auxiliary device, the female heat pipe comprises at least one open end; and
at least one male heat pipe mounted in the main device, the at least one male heat pipe comprising an inserting end;
wherein the inserting end of the at least one male heat pipe is able to be movably inserted into the at least one open end.

8. The electronic device of claim 7, wherein the female heat pipe comprises a dissipation section and at least one sleeve integrally formed with the dissipation section, the at least one open end is situated in the at least one sleeve.

9. The electronic device of claim 8, wherein the dissipation section is straight.

10. The electronic device of claim 8, wherein the dissipation section is U-shaped and comprises two ends, two sleeves are integrally formed with and extend from the two ends.

11. The electronic device of claim 7, wherein the at least one male heat pipe further comprises a free end opposite to the inserting end.

12. The electronic device of claim 11, wherein the inserting end and the free end are closed ends.

13. An electronic device comprising:
a main device;
an auxiliary device; and
at least one heat pipe assembly comprising:
a female heat pipe mounted in the main device, the female heat pipe comprises at least one open end; and
at least one male heat pipe mounted in the auxiliary device, the at least one male heat pipe comprising an inserting end;
wherein the inserting end of the at least one male heat pipe is able to be movably inserted into the at least one open end.

14. The electronic device of claim 13, wherein the female heat pipe comprises a dissipation section and at least one sleeve integrally formed with the dissipation section, the at least one open end is situated in the at least one sleeve.

15. The electronic device of claim 14, wherein the dissipation section is straight.

16. The electronic device of claim 14, wherein the dissipation section is U-shaped and comprises two ends, two sleeves are integrally formed with and extend from the two ends.

17. The electronic device of claim 13, wherein the at least one male heat pipe further comprises a free end opposite to the inserting end.

18. The electronic device of claim 17, wherein the inserting end and the free end are closed ends.
